(19) United States
(12) Patent Application Publication
(10) Pub. No.: US 2018/0294374 A1
(43) Pub. Date: Oct. 11, 2018

(54) PHOTOVOLTAIC MODULE

(71) Applicant: LG Electronics Inc., Seoul (KR)

(72) Inventor: Kangseok MOON, Seoul (KR)

(21) Appl. No.: 15/947,476

(22) Filed: Apr. 6, 2018

(30) Foreign Application Priority Data
Apr. 6, 2017 (KR) 10-2017-0044965

(51) Int. Cl. H01L 31/05; H01L 31/048; H02J 3/38

(52) U.S. Cl. CPC H01L 31/05; H02J 3/383; H01L 31/048

(57) ABSTRACT

The photovoltaic module according to the present disclosure comprising a plurality of solar cells, a front substrate including a light-incident surface for receiving incident light, being disposed over the plurality of solar cells, and relaying the incident light to the plurality of solar cells, a rear substrate disposed beneath the plurality of solar cells, and an air gap positioned at least a portion between the plurality of solar cells and the front substrate.

### CROSS-REFERENCE TO RELATED APPLICATION

This application claims the priority benefit of Korean Patent Application No. 10-2017-0044965 filed on Apr. 6, 2017 in the Korean Intellectual Property Office, the disclosure of which is incorporated herein by reference.

### BACKGROUND OF THE INVENTION

### 1. Field of the Invention

The present invention relates to a photovoltaic module for generating electricity from received light.

### 2. Description of the Related Art

Increased energy consumption has caused concern over expected rapid depletion of existing energy sources, such as petroleum and coal. Thus, alternative energy sources, as alternatives to the existing energy sources, have been getting a lot of attention in recent years. Among the alternative energy sources, solar cells or photovoltaic cells are highlighted as a next-generation battery that converts solar energy directly into electric energy. However, there remain some problems of manufacturing cost, conversion efficiency and lifetime, or the like of solar cells.

Meanwhile, the recent research on solar cells have been focused on technologies related to the improvement of efficiency of solar cells. Generally, the solar cell includes a substrate and an emitter region forming one or more p-n junctions, and generates current using sunlight incident through one surface of the substrate thereof. In this instance, since a sufficient amount of incident sunlight is required to generate a voluminous amount of current, therefore a light concentration type photovoltaic module has been developed for taking advantage of concentrating of incident sunlight.

The light concentration type photovoltaic module includes an optical design for concentrating of incident sunlight. Thus, the thickness of the module becomes thick, and a tracking device is additionally required to track the sun's orbit and altitude. In addition, the light concentration type photovoltaic module has a problem in that the efficiency of light concentration decreases sharply in a case where the alignment of solar cells is not maintained, and manufacturing cost increases due to difficulty of manufacturing of the module.

### SUMMARY OF THE INVENTION

It is an object of the present disclosure to provide a photovoltaic module that reduces optical loss and increases efficiency of power generation.

It is another object of the present disclosure to provide a photovoltaic module in that the mass productivity is improved and the manufacturing cost is reduced.

It is another object of the present disclosure to provide a photovoltaic module that absorbs water or air humidity being generated inside thereof and improves reliability.

In accordance with one aspect of the present disclosure, a photovoltaic module comprising a plurality of solar cells, a front substrate including a light-incident surface for receiving incident sunlight, being disposed over the plurality of solar cells, and relaying the incident sunlight to the plurality of solar cells, a rear substrate disposed beneath the plurality of solar cells, and an air gap positioned between the plurality of solar cells.

In addition, the refractive index of the air gap is lower than that each of the front substrate and the solar cells.

### BRIEF DESCRIPTION OF THE DRAWINGS

FIG. 1 is a schematic view illustrating a photovoltaic module in accordance with an embodiment of the present disclosure.

FIG. 2 is a floor plan view illustrating a front substrate of FIG. 1.

FIG. 3 is a cross section view illustrating “A” portion of FIG. 2.

FIGS. 4 and 5 are views illustrating different paths of light between a case where an air gap is present and a case where a medium is filled inside the photovoltaic module.

FIG. 6 is a cross section view illustrating a photovoltaic module including a front substrate in accordance with another embodiment of the present disclosure.

FIG. 7 is a cross section view illustrating a photovoltaic module including a front substrate in accordance with another embodiment of the present disclosure.

FIG. 8a is a cross section view illustrating a photovoltaic module including a rear substrate in accordance with an embodiment of the present disclosure.

FIG. 8b is a perspective view illustrating the rear substrate as shown in FIG. 8a.

FIG. 9 is a cross section view illustrating a photovoltaic module in accordance with another embodiment of the present disclosure.

FIG. 10 is a cross section view illustrating a photovoltaic module including a sealing element in accordance with an embodiment of the present disclosure.

FIG. 11 is a cross section view illustrating a photovoltaic module including a sealing element in accordance with another embodiment of the present disclosure.

### DETAILED DESCRIPTION OF THE PREFERRED EMBODIMENTS

Advantages, features and demonstration methods of the disclosure will be clarified through various embodiments described in more detail below with reference to the accompanying drawings. The disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Further, the present invention is only defined by scopes of claims. Wherever possible, the same reference numbers will be used throughout the specification to refer to the same or like parts.

Spatially relative terms such as “below”, “beneath”, “lower”, “above”, “upper”, or the like may be used easily to describe one element's relationship to another element as illustrated in the figures. It will be understood that spatially relative terms are intended to encompass different orientations of the device in addition to the orientation depicted in the figures. For example, if the device in one of the figures is turned over, elements described as “below” or “beneath” other elements would then be oriented “above” the other elements. The exemplary terms “below” or “beneath” can, therefore, encompass both an orientation of above and below. Since the device may be oriented in another direction, the spatially relative terms may be interpreted in accordance with the orientation of the device.

The terminology used in the present disclosure is for the purpose of describing particular embodiments only and is not intended to limit the disclosure. As used in the disclosure, the singular forms “a”, “an” and “the” are intended to include the plural forms as well, unless context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In the drawings, the thickness or size of each layer is exaggerated, omitted, or schematically illustrated for convenience of description and clarity. Also, the size or area of each configured element does not entirely reflect the actual size thereof.

Angles or directions used to describe the structures of the photovoltaic module according to embodiments are based on those shown in the drawings. Unless there is, in the specification, no definition of a reference point to describe angular positional relations in the structures of the photovoltaic module, the associated drawings may be referred to.

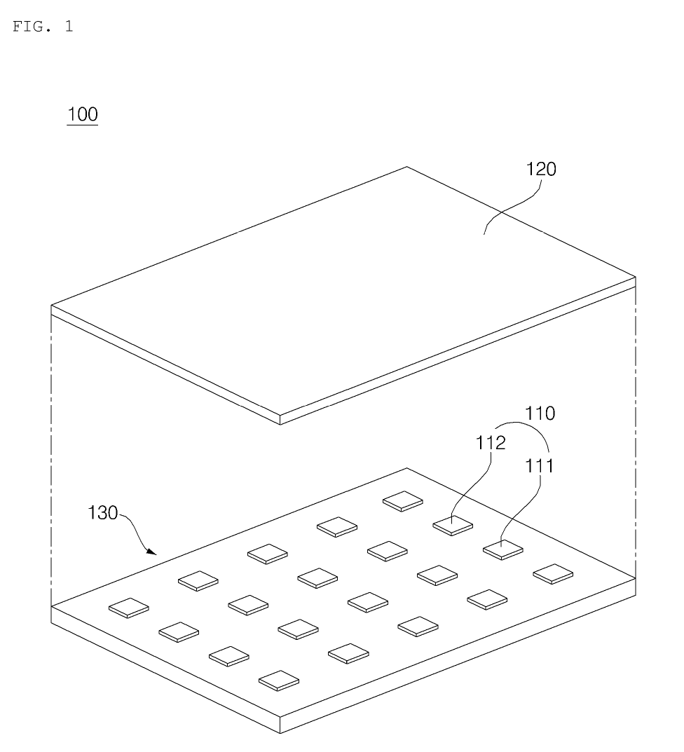

FIG. 1 is a schematic view illustrating a photovoltaic module in accordance with an embodiment of the present disclosure.

Referring to FIG. 1, a photovoltaic module 100 according to the embodiment may include at least one solar cell 110, a front substrate 120, an air gap 140 and a rear substrate 130.

The solar cells 110 include a photoelectric conversion portion converting solar energy into electric energy, and electrodes electrically connected to the photoelectric conversion portion. In this preferred embodiment, the photoelectric conversion portion which includes a semiconductor substrate, such as a silicon wafer, or a semiconductor layer, such as a silicon layer, may be applied to the solar cells 100.

The solar cells 110 include ribbons and may be electrically connected in series or parallel or in various combinations thereof, such as series-parallel connection by ribbons. More specifically, electrodes of a first and second solar cell 111 and 112 which are positioned in proximity to each other may be connected to each other with the ribbons. Specific configuration of the solar cells 110 will be described in detail later.

The front substrate 120 may be positioned over a front surface or a top surface of the solar cell 110a, and function as any substrate on which sunlight is incident. In this case, the front substrate 120 is spaced apart from the solar cell 110, and disposed to cover the solar cell 110. The front substrate 120 may be performed by an optical sheet having configurations in which reflecting of sunlight is prevented and transmittance thereof is increased. Furthermore, the front substrate 120 is configured to perform an optical function in which sunlight is concentrated and relayed toward inside the photovoltaic module 100. The optical sheet may be set to a thickness of 10 mm or less. In this case, the front substrate 120 may be any front substrate having a function for protecting the solar cell 110 from external impact in addition to optical function.

The rear substrate 130 may be performed by a rear sheet which supports the rear side of the solar cell 110 and has the form of a film or a sheet. The rear sheet is positioned beneath the solar cell 110, and it is a layer for protecting the solar cell 110 and has functions of waterproof, insulating, and ultraviolet shielding. The rear sheet may be configured to have the form of a film or a sheet. In this case, the rear substrate 130 may be made of a material or be adapted to a configuration having excellent reflectance so that incident sunlight being concentrated by the front substrate 120 can be reflected and reused.

The front substrate 120 may perform a function which reflects the light reflected by the rear substrate 130 again and relays the reflected light toward inside the photovoltaic module 100, and thus confines it inside the photovoltaic module 100 or allows it to be reflected totally. Thus, the front and rear substrates 120 and 130 are configured to be combined, and as a result, the power generation efficiency of the solar cell 110 can be increased.

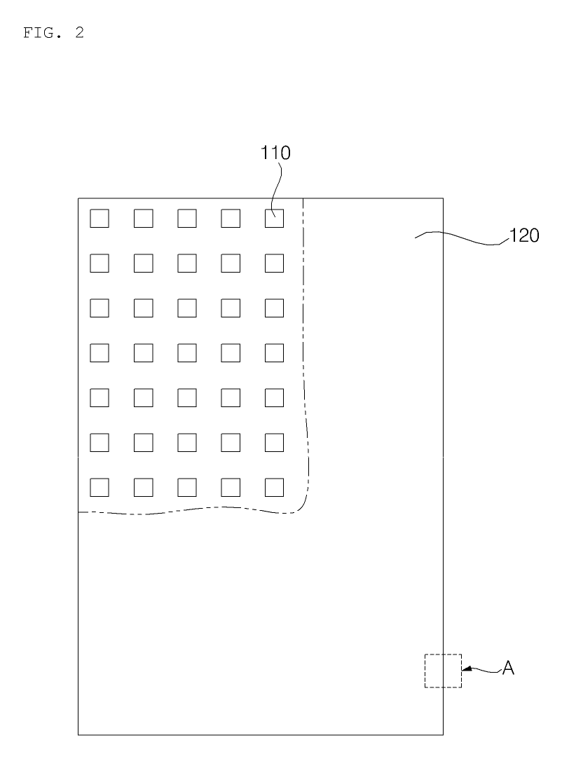

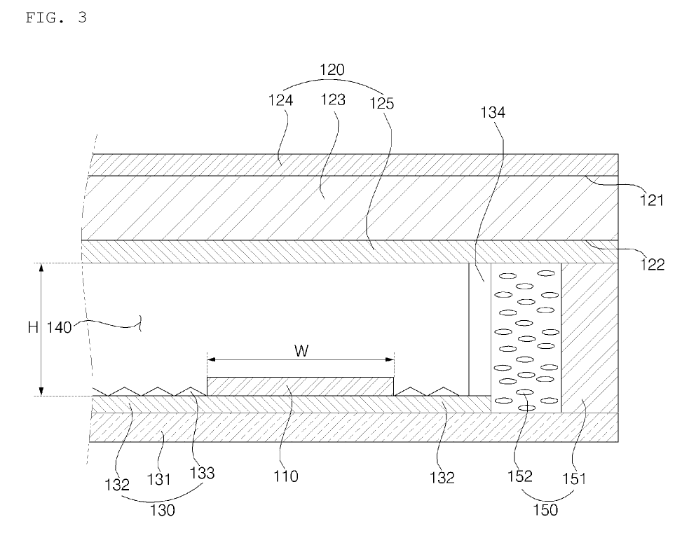

Hereinafter, in addition to illustration of FIG. 1, referring to FIGS. 2 and 3, specific configurations of the front substrate 120, the air gap 140 and the rear substrate 130 will be described in detail below.

FIG. 2 is a floor plan view illustrating the front substrate of FIG. 1, and FIG. 3 is a cross section view illustrating “A” portion of FIG. 2.

Referring to FIGS. 2 and 3, the front substrate 120 includes a light-incident surface on which sunlight is incident and it is disposed apart from a plurality of solar cells 110. The front substrate 120 is configured to concentrate the incident sunlight and relays it to be delivered.

The front substrate 120 is configured to form an outer surface of the photovoltaic module 100, and thus the light-incident surface forms the outer surface of the photovoltaic module 100 Since the outer surface is the light-incident surface, the light-incident surface on which light is incident may be prevented from contaminating by dust or the like.

The refractive index of the front substrate 120 is lower than that of the solar cell 110. Alternatively, the refractive index of the front substrate 120 may be higher than that of the air gap 140. The refractive index of the front substrate 120 is higher than that of the air gap 140 and lower than that of the solar cell 110 (specifically, a GaAs layer 110a and antireflection films 110b and 110c), and as a result of this, reflecting of the sunlight incident from the outside to the front substrate 120 may be alleviated and the total reflection of the light incident from the front substrate 120 to the air gap 140 may be alleviated. Consequently, an amount of light being delivered from the outside to the air gap 140 though the front substrate 120 may be increased and a light receiving efficiency may be increased.

For example, the front substrate 120 may be formed as a single layer. More specifically, the front substrate 120 includes a base element 123. The base element 123 may be a plate-shaped sheet of a light-transmitting material, and formed of a material such as glass, PMMA (Poly Methyl Meta Acrylate), a polymer such as silicone, or the like. Furthermore, the front substrate 120 may be any low iron tempered glass with a low iron content in order to prevent reflecting of sunlight and increase transmittance thereof. No limitation to this is imposed, the base element 123 may be formed of another material.

As another embodiment, the front substrate 120 may include a plurality of layers alleviating the reflection of light which is made on the boundary of the front substrate 120. More specifically, refractive indexes of the plurality of layers included in the front substrate 120 may be different from one another, and preferably, any layer being relatively closely disposed to one or more solar cells 110 of layers included in the front substrate 120 may have a refractive index lower than a layer being disposed relatively far away from the one or more solar cells 110. As another embodiment, any layer being closely disposed to the outside of the photovoltaic module 100 of layers included in the front substrate 120 may have a refractive index lower than a layer being disposed relatively far away from the outside of the photovoltaic module 100.

More specifically, in order to alleviate reflection between the front substrate 120 and the outside, and alleviate total reflection between the front substrate 120 and the air gap 140, the front substrate 120 may include a base element 123, a first coating layer 124 disposed thereon and a second coating layer 125 disposed therebeneath.

The first coating layer 124 is configured to cover the whole top surface of the base element 123 in correspondence with the base element 123. The first coating layer 124 may include a plate-shaped sheet of a light-transmitting material. A refractive index of the first coating layer 124 is higher than that of air and lower than that of the base element 123. As a result of this, the reflection of light made between the outside and the base element 123 may be reduced by the first coating layer 124. Preferably, the refractive index of the first coating layer 124 is 1.2 to 1.4, and the refractive index of the base element 123 is 1.5 to 1.7. The first coating layer 124 may be composed of SiOₓ, SiNₓ, AlₓO_{y}, MgF₂ and ZnS. The first coating layer 124 may be composed of multiple layers, and may have a configuration in which the more it is adjacent to the base element 123, the more the refractive index increases.

The second coating layer 125 is configured to cover the whole bottom surface of the base element 123 in correspondence with the base element 123. The second coating layer 125 may include a plate-shaped sheet of a light-transmitting material. A refractive index of the second coating layer 125 is higher than that of the air gap 140 and lower than that of the base element 123. As a result of this, the total reflection of light made between the air gap and the base element 123 may be reduced by the second coating layer 125 Preferably, the refractive index of the second coating layer 125 is 1.2 to 1.4, and the refractive index of the base element 123 is 1.5 to 1.7. The second coating layer 125 may be composed of SiOₓ, SiNₓ, AlₓO_{y}, MgF₂ and ZnS. The second coating layer 125 may be composed of multiple layers, and may have a configuration in which the more it is adjacent to the base element 123, the more the refractive index increases.

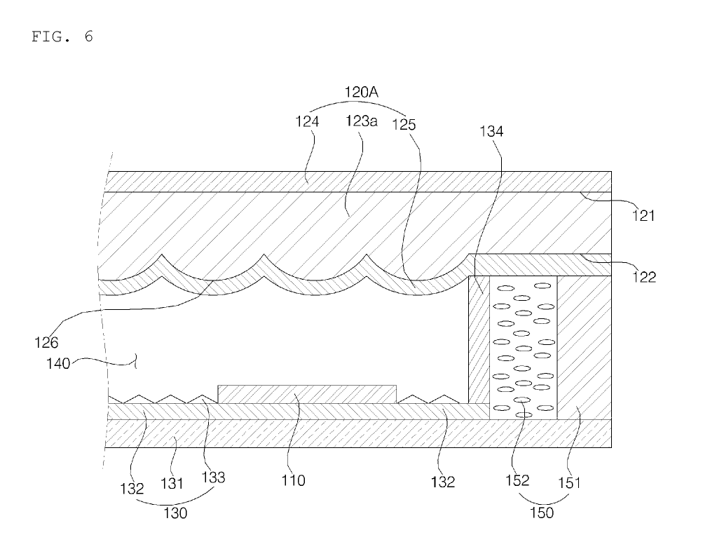

The front substrate 120 may be configured to be flat. More specifically, each of the light-incident surface 121 and the light-emission surface 122 of the front substrate 120 may be configured to be flat. Yet more specifically, each of the top surface and the bottom surface of the base element 123 may be configured to be flat. The first coating layer 124 may be configured to be flat in correspondence with the top surface of the base element 123, and the second coating layer 125 may be configured to be flat in correspondence with the bottom surface of the base element 123. The front substrate 120 may be configured to have a concentrating configuration which concentrates and relays light incident from the outside. Any configuration for concentrating light by the front substrate 120 will be described in connection with FIG. 6 later.

The air gap 140 may be formed within any reason between the front substrate 120 and the at least one solar cells 110, function as a buffer zone that protects the solar cell 110 from external impact, and alleviate the reflection of light made at the interface of the solar cell 110.

Each solar cell 110 includes a coated anti-reflection film which has a refractive index between the solar cell 110 and air in order to alleviate reflecting of light incident from the outside at the interface of the solar cell 110.

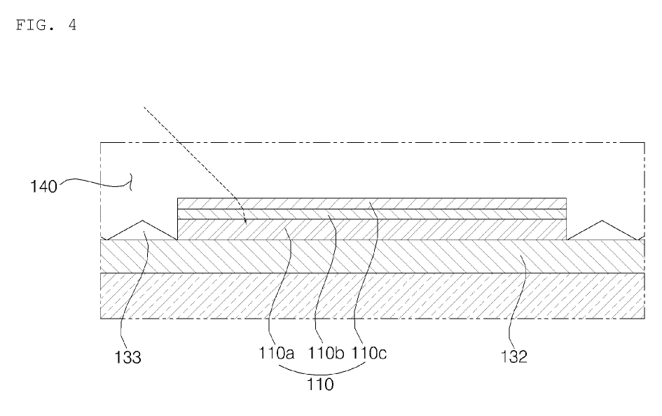

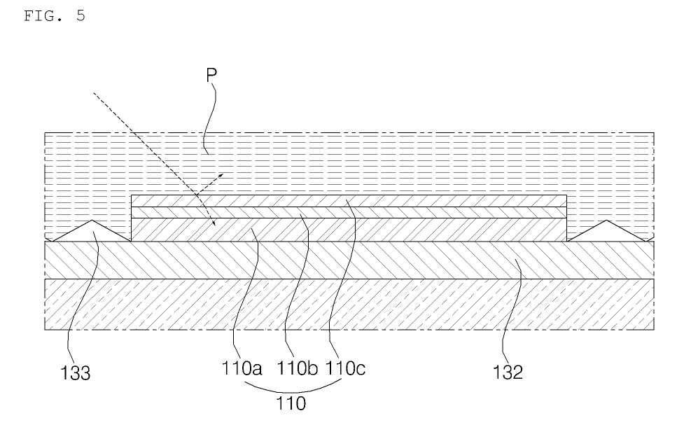

In a case where the solar cell 110 having the coated anti-reflection film is sealed with an encapsulant, an encapsulant having a refractive index higher than the anti-reflection film of the solar cell 110 is being used, and rather, light being absorbed to the solar cell 110 becomes reduced. The detailed description on this will be given in connection with FIGS. 4 and 5.

An air gap 140 may be used in order to alleviate reflecting of light on the anti-reflection film of the solar cell 110. The air gap 140 may be defined as an empty space between the front substrate 120 and the solar cell 110.

The air gap 140 may be additionally formed between the solar cells 110 and the rear substrate 130 Thus the air gap 140 may be defined as the space between the solar cells 110 and the front substrate 120, as an embodiment having a small space, or the whole space in which the solar cells 110 are accommodated, which are positioned between the front substrate 120 and the rear substrate 130, as an embodiment having a large space.

The refractive index of the air gap 140 is lower than that of solar cells 110 and that of the front substrate 120 More specifically, the refractive index of the air gap 140 is lower than that of solar cells 110 and that of the anti-reflection film of solar cells 110. The refractive index of the air gap 140 is lower than that of the first coating layer 124 and that of the second coating layer 125.

light passed through the front substrate 120 enters air, and thus an angle of refracting from the front substrate 120 toward the solar cell 110 may increase as compared with a case where a medium having a refractive index higher than air fills an empty space. As a result of this, the effect of light being further concentrated toward the solar cell 110 can be exerted.

Meanwhile, as air is present in the air gap 140, loss of light incident into the solar cell 110 may be reduced.

Only air may be present, or an inert gas such as Ar, or the like may be charged, or the inert gas mixed with air may be charged, in the air gap 140. While the photovoltaic module 100 has generally a configuration in which a material such as resin fills an empty space, in this preferred embodiment, an empty space in which air or the inert gas is present is formed, and thus leakage of light resulted from refractive index difference can be mitigated or prevented. As the refractive index of air is about 1, a refractive index of the front substrate 120 is preferably a higher value, for example 1.3 to 1.5, than that of air.

Meanwhile, the rear substrate 130 is disposed beneath one or more solar cells 110. The rear substrate 130 is configured to define a space for accommodating the solar cell 110 along with the front substrate 120, and supports the solar cell 110. Furthermore, the rear substrate 130 may additionally include a reflection member which is disposed between solar cells 110, and reflects light.

For example, the rear substrate 130 may include a base substrate 131 and a rear reflective layer 132.

The base substrate 131 is a substrate supporting the solar cell 110, and may be formed as material such as, glass, PC (polycarbonate), PMMA (Poly Methyl Meta Acrylate), or the like. As another example, the base substrate 131 is a layer for protecting the solar cell 110, and it may be a type of TPT (Tedlar/PET/Tedlar) which has a function of waterproof, insulating and UV protection, or a configuration in which polyvinylidene fluoride (PVDF) resin or the like is formed on at least one side of polyethylene terephthalate (PET).

The rear reflective layer 132 may be a reflective sheet attached or a coating layer coated on the top surface of the base substrate 131. In this case, the one or more solar cells 110 may be mounted on at least one surface of the base substrate 131, and the rear reflective layer 132 may be disposed on a surface of the base substrate 131 or the solar cell 110. The rear reflective layer 132 may be entirely or partially disposed on the top surface of the base substrate 131, and the solar cell 110 may be disposed on the top surface of the rear reflective layer 132. In accordance with this configuration, the rear reflective layer 132 reflects light being present between the solar cells 110. No limitation to this is imposed, and in an embodiment, one or more solar cells 110 may be disposed on the top surface of the base substrate 131, and the rear reflective layer 132 may be disposed between the solar cells 110. This embodiment will be described later.

In this case, the rear reflective layer 132 may include a plurality of protrusions 133. A wrinkle or concavo-convex pattern may be provided on the rear reflective layer 132 by the plurality of protrusions 133, and this allows the light to be reflected in a wider range.

By this structure, the light which has passed through the front substrate 120 is confined between the front substrate 120 and the rear substrate 130. That is, the light which has passed through the front substrate 120 may be recycled inside the photovoltaic module 100, and absorbed to cells of the solar cell 110. The light traveling from the air gap 140 to the front substrate 120 is confined by the total reflection which is made in the course of traveling of the light from a light medium to a thick medium, and the light traveling from the air gap 140 to the rear substrate 130 is confined by the rear reflective layer.

The solar cell 110 according to this embodiment may be a gallium arsenide solar cell 110 or a silicone solar cell 110, and an anti-reflection film may be disposed on the outside thereof. Hereinafter, a case where the solar cell 110 is the gallium arsenide solar cell 110 will be described as a main embodiment.

FIG. 4 is a simplified illustration of a typical solar cell 110.

Referring to FIG. 4, for example, the gallium arsenide solar cell 110 may include an anti-reflection film which has a refractive index lower and higher than GaAs and air respectively, and which is disposed on an outer surface of a GaAs layer 110a. As another example, the silicone solar cell 110 may include an anti-reflection film on an outer surface of a Si layer. For example, the material of the anti-reflection film may be SiOₓ, SiNₓ, AlₓO_{y}, MgF₂, ZnS, or the like, and also a material typically used in the solar cell 110. In this case, the anti-reflection film may have a single layer, or a plurality of layers in order to further increase an absorption rate of light inside cells. In this case, the anti-reflection film may include a first layer 110b of ZnS, and a second layer 111c of MgF₂.

Since refractive indexes of GaAs, ZnS, MgF, and air covering MgF2 are about 3.4, 2.38, 1.38, and 1 respectively, when light is sequentially incident to the second layer 111c, the first layer 110b and the GaAs layer 110a in the air gap 140, the loss of the light becomes very small because the refractive index gradually increases according to a path of the light.

As another example, as shown in FIG. 5, in a case where a medium is filled instead of air, there is little or no difference in the refractive index between MgF2 and the medium. In this case, a surface loss in the anti-reflection film of the solar cell 110 can be increased. As such an example, in a case where the medium is a polymer (P), the refractive index is about 1.3 to 1.5. Accordingly, when light is incident from the polymer to the second layer 111c, the difference in the refractive index between the polymer and MgF2 hardly occurs, or the refractive index becomes negative, and thus the reflection of light on the surface of the solar cell 110 further becomes increased

Likewise, in a case where the silicon solar cell 110 is used, the antireflection film which is disposed on the solar cell 110 is composed of a single layer or a plurality of layers with a material having a refractive index lower than that of the solar cell 110 (for example, SiNx), and thus more light can be absorbed into the solar cell 110

Meanwhile, the thickness (H) of the air gap 140 may be greater than or equals to one-half of the width (W) of the solar cell 110. Thus, a sufficient space for totally reflecting light can be secured. As an example of this, the distance between the front substrate 120 and the rear substrate 130 may be less than or equals to 50 mm.

The air gap 140 may be sealed by bonding together the edges of the front substrate 120 and the rear substrate 130, or sealed with a sealing element 150 between the front substrate 120 and the rear substrate 130.

For example, the sealing element 150 for sealing the air gap 140 may be disposed on edges of the front substrate 120 and the rear substrate 130. In this case, a double sealing structure using a high moisture resistant material may be applied to the sealing element 150. Furthermore, the sealing element 150 may have a double structure in which rigidity and a moisture absorption rate are different from each other.

For example, the sealing element 150 may have a first and second sealing element 151 and 152 disposed on the outside and inside thereof respectively. The second sealing element 152 is disposed adjacent to the air gap 140 than the first sealing element 151.

The first sealing element 151 is formed with a material as an adhesive thermoplastic starch (TPS), silicone, thermoplastic elastomer (TPE), or the like, and it is mounted on the base substrate 131 and thus supports the front substrate 120. Thus, the first sealing element 151 may form an outer side wall of the photovoltaic module 100. In a preferred embodiment, the first sealing element 151 may be a material having higher rigidity than the second sealing element 152. The first sealing element 151 maintains a spacing between the front substrate 120 and the rear substrate 130, and a structure of the photovoltaic module 100.

The second sealing element 152 may be composed of a rubber material such as polyisobutylene (PIB) or the like and a moisture absorbent. The second sealing element 152 may be porous to absorb moisture.

As in the first sealing element 151, the second sealing element 152 is mounted on the base substrate 131, and thus supports the front substrate 120. The second sealing element 152 is disposed on the inner side wall of the first sealing element 151, and configured to be adhered to it.

In this case, the rear reflective layer 132 of the rear substrate 130 may have an extension portion 134 extending from the base substrate 131 toward the front substrate 120 to cover the inner side wall of the second sealing element 152.

The sealing element 150 may be formed by joining the front substrate 120, after at least one photovoltaic cell is combined with the base substrate 131 or the rear reflective layer 132. That is, in a state where the front substrate 120 is prepared separately, after the sealing element 150 is attached on the base substrate 131, the front substrate 120 is joined to the sealing element 150, and thus the air gap 140 is formed.

Meanwhile, a modification to the structure of the photovoltaic module 100 of an embodiment described above can be performed to further improve efficiency of light concentration. An example of this modification, the light concentration can be obtained by arrangements of lenses. Hereinafter, this structure will be described with reference to FIG. 6.

FIG. 6 is a cross section view illustrating a photovoltaic module including a front substrate 120 in accordance with another embodiment of the present disclosure.

Referring to FIG. 6, the front substrate 120 includes a light-incident surface 121 which may be configured to be flat and a light-emission surface 122 which may be in the form of a lens. In this case, the photovoltaic module 100 as in the embodiments described above may include at least one solar cell 110, a front substrate 120 or 220, and a rear substrate 130. The solar cell 110 and the rear substrate 130 may have substantially the same structure as the above-described embodiments, and thus the description thereof is omitted.

The front substrate 120 may be disposed on the opposite side of the light-incident surface 121, and have a plurality of lenses 126 which are configured to be formed in a convex shape toward the solar cell 110.

The plurality of lenses 126 may be formed at a lower portion of the base element 123, such as at the light-emission surface 122. Accordingly, the plurality of lenses 126 may be integrated into and/or have the same material as the base element 123. No limitation to this is imposed, and in an embodiment, the plurality of lenses 126 may be a separate lens-shaped member attached on the bottom surface of the base element 123.

In addition, the plurality of lenses 126 are matched to the solar cell 110 at a ratio of many to one. No limitation to this is imposed, and in an embodiment, arrangement of the plurality of lenses 126 to the solar cell 110 may be achieved at a ratio of one to one. In a case where the plurality of lenses 126 and the solar cells 110 are matched to each other at the ratio of one to one, the center of each of the lenses 126 and the center of the solar cells 110 may be arranged to coincide with each other.

The thickness and area of the convex lens can be set based on the focal length. According to this structure, light can be concentrated toward the lower portion of the convex lens while it is incident.

In this case, a first coating layer 124 is disposed flat on the light-incident surface 121 of the base element 123, and a second coating layer 125a is configured to cover the bottom surface of the base element 123 and be convexly formed along the shape of the plurality of lenses 126.

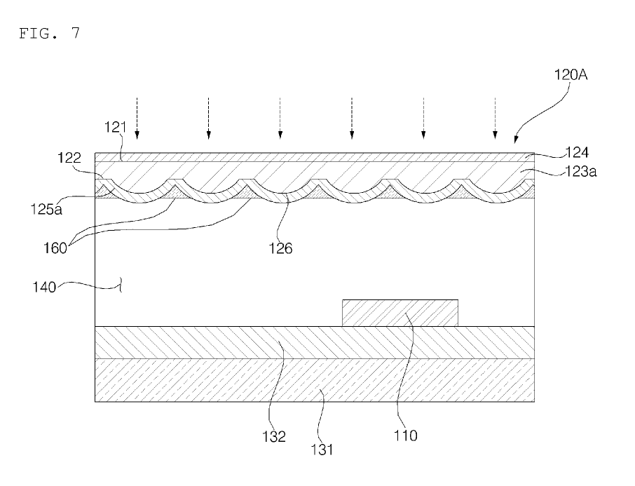

FIG. 7 is a cross section view illustrating a photovoltaic module including a front substrate 120 in accordance with another embodiment of the present disclosure.

Referring to FIG. 7, a photovoltaic module 100 according to another embodiment may further include a front reflective layer 160 as compared with the embodiment of FIG. 6.

The front reflective layer 160 may be disposed on at least one portion of the surface opposite the light-incident surface 121 of the front substrate 120, and thus the light incident through the front substrate is confined between the front substrate 120 and the rear substrate 130. The front reflective layer 160 may include a metal or resin material that reflects light.

More specifically, the front reflective layer 160 may be formed by coating a portion of the bottom surface of a light-emission surface 122 or a second coating layer 125 of the front substrate 120.

Yet more specifically, the front reflective layer 160 may be formed by performing a mirror coating on the outer surface of the plurality of lenses 126 except for a portion of the end thereof. Thus, a plurality of apertures are formed in the front reflective layer 160 or 122 so that the incident sunlight is passed through the plurality of lenses 126 and then it is delivered.

More specifically, the front reflective layer 160 may be coated on an area except for a certain area of the center portion of each of the plurality of lenses 126.

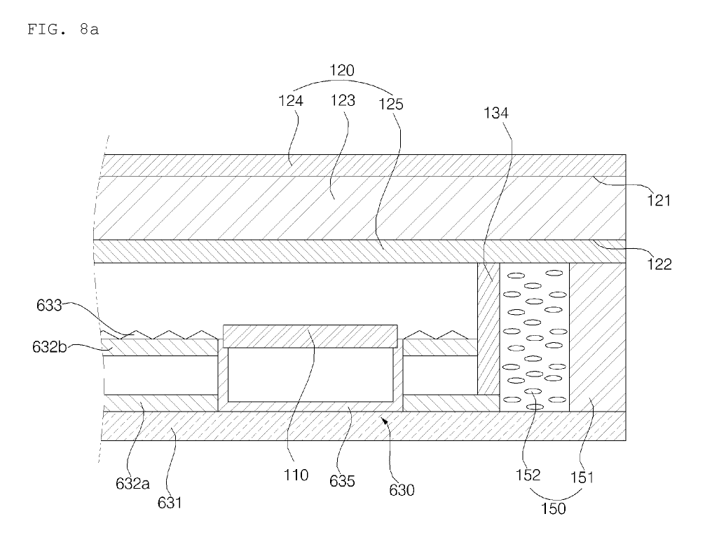

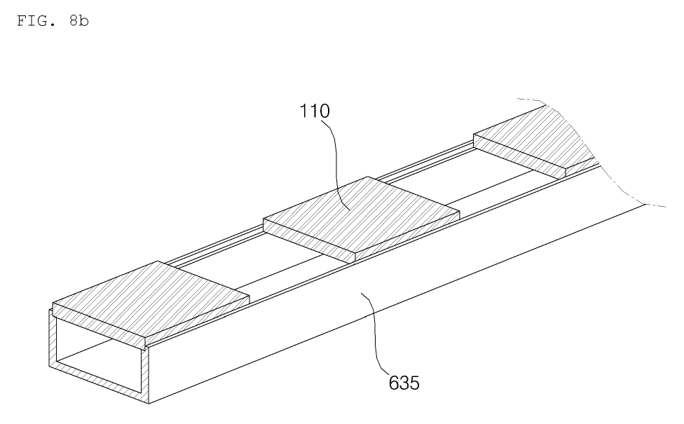

FIG. 8a is a cross section view illustrating a photovoltaic module 100 including a rear substrate in accordance with an embodiment, and FIG. 8b is a perspective view illustrating the rear substrate as shown in FIG. 8a.

Referring to FIG. 8, the rear substrate 630 may be performed as a rear sheet which supports the rear surface of the solar cell 110 and has the form of a film or sheet. The rear sheet is positioned on the rear surface of the solar cell 110, and it is a layer for protecting the solar cell 110 and has functions of waterproof, insulating, and ultraviolet shielding. The rear sheet may be configured to have the form of a film or a sheet. In this case, the rear substrate 630 may be made of a material or be adapted to a configuration having excellent reflectance so that incident sunlight being concentrated by the front substrate 120 can be reflected and thus reused.

In this case, the photovoltaic module 100 as in the embodiments described above may include at least one solar cell 110, a front substrate 120, and a rear substrate 630. The front substrate 120 may have substantially the same structure as at least one or at least one embodiment of FIGS. 1 to 7, and thus the description thereof is omitted.

The solar cell 110 according to an embodiment may be composed of bifacial cells which absorb sunlight from both the top and bottom sides thereof and then generate electricity. In addition, the solar cell 110 may be disposed side by side with a second reflector 632b. That is, the top surface of the solar cell 110 may be face the front substrate 120, and the bottom surface thereof may be face a first reflector 632a.

Meanwhile, the rear substrate 630 may include a base substrate 631, a first reflector 632a and a second reflector 632b.

The base substrate 631 is a substrate supporting the solar cell 110, and may be formed as material such as, glass, PC (polycarbonate), PMMA (Poly Methyl Meta Acrylate), or the like. As another example, the base substrate 631 is a layer for protecting the solar cell 110, and it may be a type of TPT (Tedlar/PET/Tedlar) which has a function of waterproof, insulating and UV protection, or a configuration in which polyvinylidene fluoride (PVDF) resin or the like is formed on at least one side of polyethylene terephthalate (PET).

The rear reflective layer 632a may be a reflective sheet attached or a coating layer coated on the top surface of the base substrate 631.

The second reflector 632b is disposed along with the solar cell 110 between the base substrate 631 and the front substrate 120. In this case, at least one solar cell 110 is disposed between the second reflectors 632b, and thus the second reflectors 632b fill between the solar cells 110 and light traveling between the solar cells 110 can be reflected. In this case, the second reflector 632b may include a plurality of protrusions 633. The second reflector 632b may be provided with a wrinkle or concave structure by the plurality of protrusions 633, and as a result of this, light can be reflected in a wider range.

Meanwhile, a support member 635 which supports the second reflector 632b and the solar cell 110 may be provided inside the photovoltaic module 100. The support member 635 is a ladder-type holding frame mounted on the base substrate 631. At least a part of the support member 635 protrudes toward the front substrate 120, and the solar cell 110 can be positioned on the protruding part.

Furthermore, the support member 635 may be formed of a light transmissive material, and may be configured to allow light to pass through it and enter the rear surface of the solar cell 110. In this case, the support member 635 is formed as an empty space in which air exists, and thus the light can easily enter the rear surface of the solar cell 110.

According to the above-described structure, since the light is confined in the upper and lower sides of the solar cell 110, the amount of power generation of the solar cell 110 can be further increased.

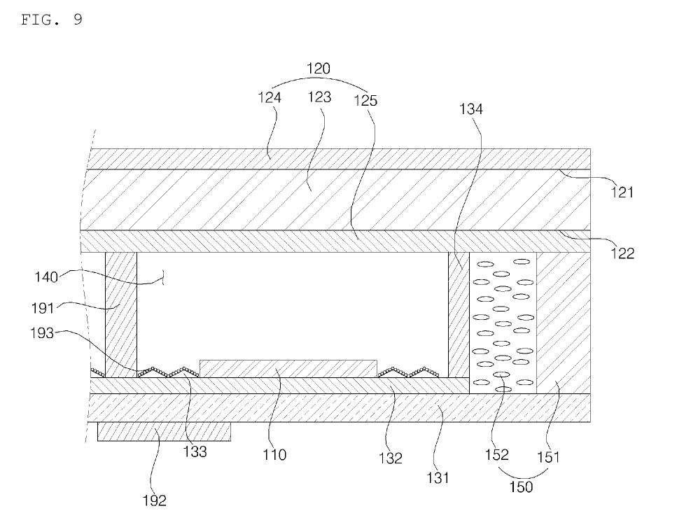

FIG. 9 is a cross section view illustrating a photovoltaic module 100 in accordance with another embodiment of the present disclosure.

In this case, the photovoltaic module 100 as in the embodiments described above may include at least one solar cell 110, a front substrate 120, and a rear substrate 630. These structures may have substantially the same structure as at least one or at least one embodiment of FIGS. 1 to 8. However, in this embodiment, description will be given on the basis of the embodiments of FIG. 3, and thus the description thereof is omitted.

A spacer 191 may be disposed between the front substrate 120 and the rear substrate 130 in order to maintain a spacing between the front substrate 120 and the rear substrate 130. The spacer 191 is mounted on the rear substrate 130 and supports the front substrate 120, and thus maintains an air gap 140. More specifically, the spacer 191 is mounted on a base substrate 131 of the rear substrate 130 or a rear reflective layer 132. It protrudes in the thickness direction of the photovoltaic module 100 and, thus can support the front substrate 120.

In addition, a reinforcing member 192 may be mounted on the bottom surface of the base substrate (131) for reinforcing rigidity. The reinforcing member 192 is mounted on a part of the base substrate 131 as a plate-shaped member, and reinforces the rigidity by surface contact with the bottom surface of the base substrate 131.

Furthermore, the rear substrate 130 may be coated with a wavelength conversion material 193 that converts the wavelength of the infrared rays into the wavelength of the visible light. The wavelength conversion material 193 may be, for example, a lanthanide-based material such as a phosphor synthesized with er3+, yb3+.

Although the light includes the infrared rays, since the solar cell 110 uses visible rays for power generation, therefore, the amount of power generated by the solar cell 110 may be increased as infrared rays are converted into visible light. In this case, light is scattered by the wavelength conversion material 193 and thus the path of the light can be randomly changed. However, according to the structure of this embodiment, the light inside the photovoltaic module 100 is recycled, and therefore the efficiency of power generation is not deteriorated.

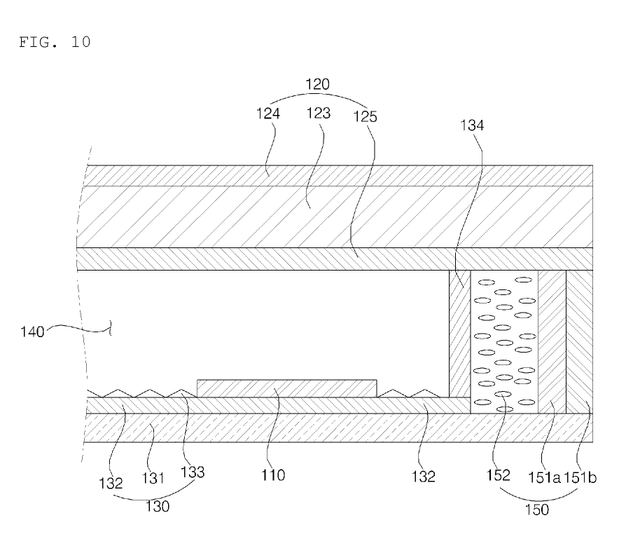

FIG. 10 is a cross section view illustrating a photovoltaic module 100 including a sealing element 150 in accordance with an embodiment of the present disclosure.

Referring to FIG. 10, the photovoltaic module 100 as in the embodiments described above may include at least one solar cell 110, a front substrate 120, and a rear substrate 630. These structures may have substantially the same structure as at least one or at least one embodiment of FIGS. 1 to 9. However, in this embodiment, description will be given on the basis of the embodiment of FIG. 3, and thus the description thereof is omitted.

The sealing element 150 in accordance with another embodiment has a first sealing element 151 having a double structure. For example, the first sealing element 151 may include a sealing material 151b having adhesion and sealing force, and a frame 151a having a higher rigidity than the sealing material 151b.

The frame 151a includes a resin or metal material having a higher rigidity than the sealing material 151b. The frame 151a is disposed further inside than the sealing material 151b and provides a supporting force for supporting the front substrate 120 between the front substrate 120 and the rear substrate 130.

The sealing material 151b includes a resin material having adhesion and sealing force. The sealing material (151b) is disposed a further outside than the frame 151a. The frame 151a is disposed between the sealing material 151b and the second sealing element 152. Foreign material is prevented from being introduced from the outside by the sealing material 151b.

Thus, the first sealing element 151 has a double structure of the frame 151a and the sealing material 151b. Because of this, the rigidity of the photovoltaic module 100 can be maintained and the spacer disposed in the middle can be removed, and therefore, an advantage of maintaining the sealing power by the sealing material is obtained.

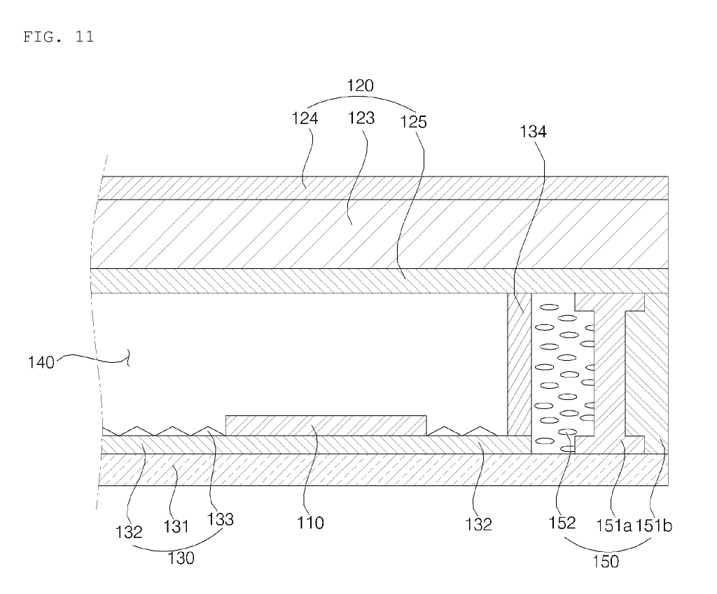

FIG. 11 is a cross section view illustrating a photovoltaic module 100 including a sealing element 150 in accordance with another embodiment of the present disclosure.

Referring to FIG. 11, the photovoltaic module 100 as in the embodiments described above may include at least one solar cell 110, a front substrate 120, and a rear substrate 630. These structures may have substantially the same structure as at least one or at least one embodiment of FIGS. 1 to 10. However, in this embodiment, description will be given on the basis of the embodiment of FIG. 10, and thus the description thereof is omitted.

The sealing element 150 in accordance with another embodiment has a first sealing element 151 having a double structure. For example, the first sealing element 151 may include a sealing material 151b having adhesion and sealing force, and a frame 151a having a higher rigidity than the sealing material 151b. In another embodiment, the frame 151a may have various shapes to improve rigidity. More specifically, the frame 151a may have an H beam shape. The frame 151a has the H beam shape, so that the rigidity can be maintained while reducing the manufacturing cost of the frame 151a.

Thus, since the photovoltaic module according to this embodiment described above uses the air gap, it is possible to alleviate the reflection of the incident sunlight without absorption thereof on the outer surface of the solar cell. More specifically, the surface loss of the coating film may be reduced as the solar cell is exposed in an air gap having a lower refractive index than the coating film forming the outer surface of the solar cell.

In addition, a sealing element sealing the front substrate and the rear substrate seals the air gap and absorbs moisture in the air gap through a moisture absorbent or a porous material. Therefore, it is possible to improve the reliability of the photovoltaic module.

Furthermore, according to the embodiments, the photovoltaic module can be performed as a structure capable of increasing the amount of visible rays using the wavelength conversion material.

The above-described photovoltaic module is not limited to the configuration and method of the embodiments described above, and therefore all or a part of the embodiments may be selectively combined so that various modifications may be made in the embodiments.

What is claimed is:

1. A photovoltaic module comprising:
a plurality of solar cells;
a front substrate including a light-incident surface on which light is incident, being disposed over the plurality of solar cells, and relaying the incident light to the plurality of solar cells;
a rear substrate disposed beneath the plurality of solar cells; and
an air gap disposed between the front substrate and the plurality of solar cells,
wherein the air gap includes at least one of air and inert gas, and
wherein a refractive index of the air gap is lower than the refractive index of the plurality of solar cells and the refractive index of the front substrate.

2. The photovoltaic module according to claim 1,
wherein the air gap is disposed between the plurality of solar cells and the rear substrate.

3. The photovoltaic module according to claim 1,
wherein plurality of solar cells includes a gallium arsenide.

4. The photovoltaic module according to claim 1,
wherein a thickness of the air gap is greater than or equals to one-half of a width of the solar cell.

5. The photovoltaic module according to claim 4,
wherein a refractive index of the front substrate is lower than that of the plurality of solar cells.

6. The photovoltaic module according to claim 4,
wherein the front substrate includes a plurality of layers.

7. The photovoltaic module according to claim 6,
wherein the plurality of layers of the front substrate have a different refractive index from one other.

8. The photovoltaic module according to claim 6,
wherein a layer disposed relatively close to the plurality of solar cells of layers of the front substrate has a lower refractive index than a layer disposed relatively far away from the plurality of solar cells.

9. The photovoltaic module according to claim 1,
further comprising a front reflective layer disposed on at least one portion of a surface opposite the light-incident surface of the front substrate, and confining light incident through the front substrate to between the front substrate and the rear substrate.

10. The photovoltaic module according to claim 1,
further comprising a sealing element being disposed between the front substrate and the rear substrate, and performing the sealing of the air gap.

11. The photovoltaic module according to claim 10,
wherein the sealing element includes a first sealing element and a second sealing element.

12. The photovoltaic module according to claim 11,
wherein the first sealing element has a different rigidity from the second sealing element.

13. The photovoltaic module according to claim 11,
wherein the second sealing element is disposed further adjacent to the air gap than the first sealing element and includes a moisture absorbent that absorbs moisture of the air gap.

14. The photovoltaic module according to claim 11,
wherein the second sealing element is disposed further adjacent to the air gap than the first sealing element and includes a porous material.

15. The photovoltaic module according to claim 12 or 13,
wherein the first sealing element has a greater rigidity than the second sealing element.

16. The photovoltaic module according to claim 1,
wherein the front substrate is disposed on the opposite side of the light-incident surface, and includes a plurality of lenses which are formed in a convex shape toward the plurality of solar cells.

17. The photovoltaic module according to claim 1,
further comprising a rear reflective layer formed to reflect light between the plurality of solar cells.

18. The photovoltaic module according to claim 17,
wherein the rear reflective layer includes a plurality of protrusions.

19. The photovoltaic module according to claim 1,
further comprising a spacer for maintaining a spacing between the front substrate and the rear substrate.

20. The photovoltaic module according to claim 1,
further comprising a wavelength conversion material for converting the wavelength of infrared rays into the wavelength of visible rays.
